(19) United States
(12) Patent Application Publication
(10) Pub. No.: US 2019/0139796 A1
(43) Pub. Date: May 9, 2019

(54) MONITORING APPARATUS AND SEMICONDUCTOR MANUFACTURING APPARATUS INCLUDING THE SAME

(71) Applicant: Samsung Electronics Co., Ltd., Suwon-si (KR)

(72) Inventors: Sang-kil LEE, Yongin-si (KR); Sung-yoon RYU, Suwon-si (KR); Hyun LEE, Hwaseong-si (KR); Yu-sin YANG, Seoul (KR); Q-han PARK, Seoul (KR)

(73) Assignee: Samsung Electronics Co., Ltd., Suwon-si (KR)

(21) Appl. No.: 15/956,192

(22) Filed: Apr. 18, 2018

(30) Foreign Application Priority Data
Nov. 3, 2017 (KR) 10-2017-0146181

(51) Int. Cl. H01L 21/67; H01L 21/66

(52) U.S. Cl. CPC H01L 21/67253; H01L 22/12

(57) ABSTRACT

An apparatus for manufacturing a semiconductor device is provided. The apparatus for manufacturing a semiconductor device may include a mass flow controller configured to control a flow of a process gas supplied to a process chamber, the mass flow controller configured to adjust an outflow rate of the process gas exiting the mass flow controller in response to a correction signal, the correction signal generated based on a difference between an inflow rate of the process gas flowing into the mass flow controller and a reference flow rate, a sensor configured to measure a chamber pressure inside the process chamber, an exhaust valve configured to adjust an exhaust speed of an exhaust gas exhausted from the process chamber; and a monitoring apparatus configured to detect a defect of the mass flow controller based on the correction signal, the chamber pressure, and the exhaust speed of the exhaust valve.

### CROSS-REFERENCE TO RELATED APPLICATION

This application claims priority under 35 U.S.C. § 119 to Korean Patent Application No. 10-2017-0146181, filed on Nov. 3, 2017, in the Korean Intellectual Property Office, the disclosure of which is incorporated herein in its entirety by reference.

### BACKGROUND

The inventive concepts relate to a monitoring apparatus for detecting a defect of a process condition during a semiconductor manufacturing process, and an apparatus for manufacturing a semiconductor device including the monitoring apparatus.

A semiconductor device is manufactured through a semiconductor manufacturing process including numerous unit processes such as a thin film process, a photolithography process, an etching process, and/or a diffusion process. Recently, as an influence of a change of a small process parameter on quality of a semiconductor product increases due to refinement of a circuit linewidth, etc., the importance of detecting process abnormality of a semiconductor manufacturing process at an early stage, gradually increases. In order to detect process abnormality of a semiconductor manufacturing process, a wafer can be tested after a unit process is performed, or one or more process parameters such as temperature, pressure, and/or plasma density may be monitored by using various sensors attached on a chamber in which a semiconductor process is performed.

### SUMMARY

The inventive concepts provide a monitoring apparatus which may monitor whether a flow of a process gas supplied to a process chamber is abnormal, and an apparatus for manufacturing a semiconductor device, the apparatus including the monitoring apparatus.

According to an example embodiment of the inventive concepts, an apparatus for manufacturing a semiconductor device may include a mass flow controller configured to control a flow of a process gas supplied to a process chamber, the mass flow controller configured to adjust an outflow rate of the process gas exiting the mass flow controller in response to a correction signal, the correction signal generated based on a difference between an inflow rate of the process gas flowing into the mass flow controller and a reference flow rate, a sensor configured to measure a chamber pressure inside the process chamber, an exhaust valve configured to adjust an exhaust speed of an exhaust gas exhausted from the process chamber, and a monitoring apparatus configured to detect a defect of the mass flow controller based on the correction signal, the chamber pressure, and the exhaust speed of the exhaust valve.

According to an example embodiment of the inventive concepts, an apparatus for manufacturing a semiconductor device may include a process chamber providing a process space for processing a substrate, a mass flow controller configured to control a flow rate of a process gas supplied to the process chamber, a sensor configured to measure a chamber pressure of the process chamber, an exhaust valve configured to adjust an exhaust speed of an exhaust gas exhausted from the process chamber, and a monitoring apparatus configured to detect the flow rate of the process gas supplied to the process chamber based on the chamber pressure and the exhaust speed of the exhaust gas.

According to an example embodiment of the inventive concepts, a monitoring apparatus for detecting a defect of a mass flow controller controlling a flow of a process gas supplied to a process chamber is configured to generate a correction signal based on a difference between an inflow rate of the process gas flowing to the mass flow controller and a reference flow rate, and detect a defect of the mass flow controller based on the correction signal, environment information inside the process chamber, and an exhaust speed of an exhaust gas exhausted from the process chamber.

### BRIEF DESCRIPTION OF THE DRAWINGS

Example embodiments of the inventive concepts will be more clearly understood from the following detailed description taken in conjunction with the accompanying drawings in which:

FIG. 1 is a configuration view of an apparatus for manufacturing a semiconductor device according to an example embodiment;

FIG. 2 is a block diagram of the apparatus for manufacturing the semiconductor device of FIG. 1;

FIG. 3 is a detailed configuration view of a mass flow controller illustrated in FIG. 2;

FIG. 4 is a perspective view of an exhaust valve according to an example embodiment;

FIG. 5 is a block diagram of an apparatus for manufacturing a semiconductor device according to an example embodiment;

FIG. 6 is a flowchart of a method of manufacturing a semiconductor device by using a method of monitoring a mass flow controller according to an example embodiment; and

FIGS. 7, 8, and 9 are views for explaining a method of determining a cause of a defect of a mass flow controller.

### DETAILED DESCRIPTION

Hereinafter, the inventive concepts will be described in detail by explaining some example embodiments of the inventive concepts with reference to the attached drawings. Like reference numerals in the drawings denote like elements.

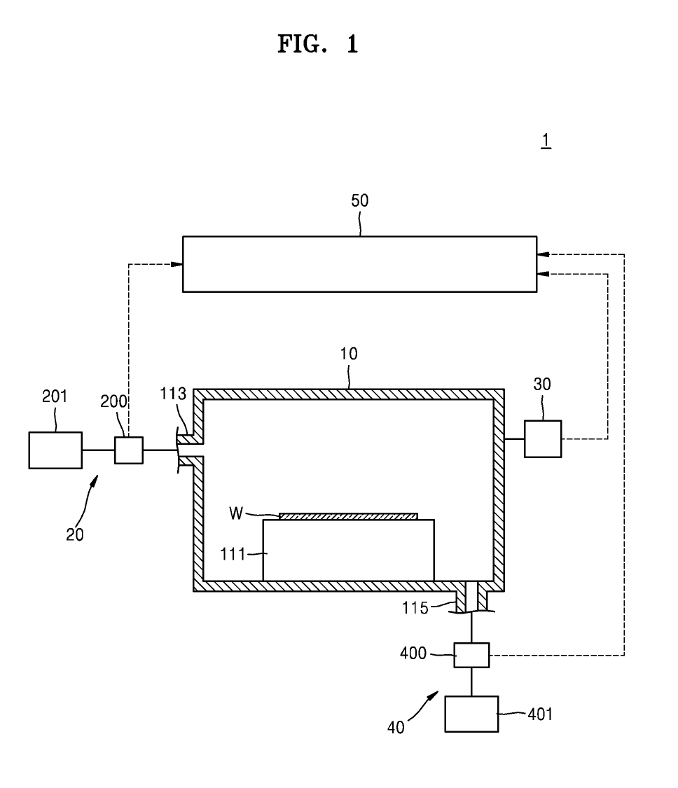

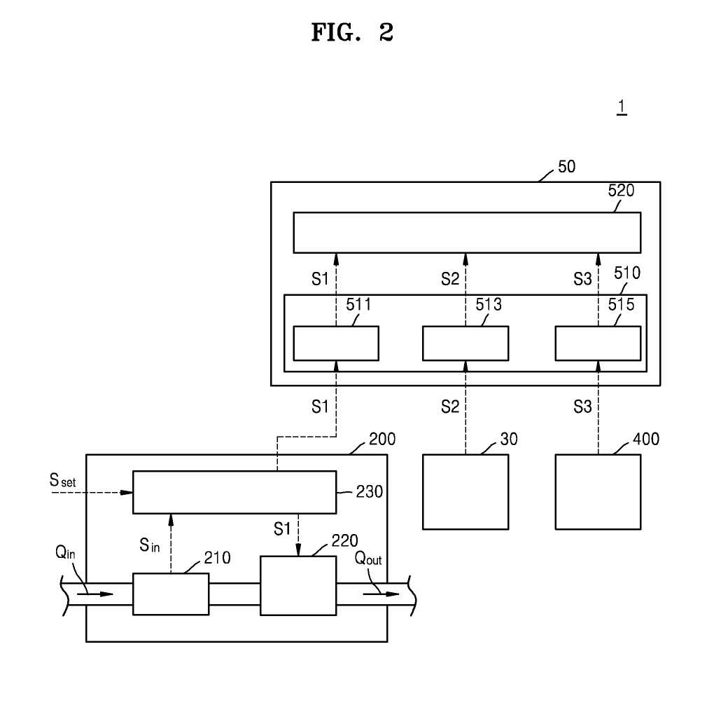

FIG. 1 is a configuration view of an apparatus 1 for manufacturing a semiconductor device according to an example embodiment. FIG. 2 is a block diagram of the apparatus 1 for manufacturing the semiconductor device of FIG. 1.

Referring to FIGS. 1 and 2, the apparatus 1 for manufacturing the semiconductor device may include a process chamber 10, a gas supplier 20, a sensor unit 30, an exhaust unit 40, and a monitoring apparatus 50.

The process chamber 10 may provide a process space for processing a substrate W, and perform a semiconductor manufacturing process, for example, a deposition process, an etching process, a diffusion process, a dry process, and a washing process. The process chamber 10 may include a substrate supporter 111 for supporting the substrate W, a gas introduction port 113 formed in a chamber wall, and a gas exhaust port 115 formed in the chamber wall.

The gas supplier 20 may supply a process gas desired for a semiconductor manufacturing process, the process gas being for processing the substrate W. The gas supplier 20 may adjust a kind of the process gas and/or a flow of the process gas supplied as the process gas according to a desired (or alternatively, preset) process recipe.

The gas supplier 20 may include a gas supply source 201 accommodating the process gas, and a mass flow controller 200 controlling a flow of the process gas supplied to the process chamber 10. The mass flow controller 200 may be provided on a gas supply line connecting the gas supply source 201 to the gas introduction port 113 of the process chamber 10. The mass flow controller 200 may control a flow of the process gas such that a reference (or alternatively, preset) flow rate of the process gas is supplied to the process chamber 10.

In the case where a flow of the process gas different from the reference (or alternatively, preset) flow rate is introduced to the mass flow controller 200, the mass flow controller 200 may adjust a flow of the process gas such that an outflow rate Qout of the process gas flowing from the mass flow controller 200 is equal to the reference (or alternatively, preset) flow rate.

The mass flow controller 200 may include a flow sensor 210, a valve unit 220, and a controller 230.

The flow sensor 210 may measure an inflow rate Qin of the process gas introduced to the mass flow controller 200. For example, the flow sensor 210 may include a mass flow meter. The flow sensor 210 may generate a signal Sin corresponding to an inflow rate Qin introduced to the mass flow controller 200.

The controller 230 may receive a set signal Sset corresponding to a reference (or alternatively, preset) signal and a signal Sin corresponding to the inflow rate Qin transmitted from the flow sensor 210, and generate a correction signal S1 based on the set signal Sset and the signal Sin corresponding to the inflow rate Qin. The correction signal S1 is a signal applied to the valve unit 220 and may be used for driving the valve unit 220 such that an outflow rate Qout flowing from the mass flow controller 200 is equal to the reference (or alternatively, preset) flow rate. The correction signal S1 may have a voltage value or a current value corresponding to a difference between the reference (or alternatively, preset) signal Sset and the signal Sin corresponding to the inflow rate Qin. The controller 230 may transmit the correction signal S1 to the valve unit 220 and the monitoring apparatus 50.

The valve unit 220 may be arranged on a channel prepared inside the mass flow controller 200, and may adjust the outflow rate Qout of the process gas flowing from or exiting the mass flow controller 200. The valve unit 220 is driven in response to the correction signal S1 applied from the controller 230, and may adjust an opening degree of the channel inside the mass flow controller 200 such that the outflow rate Qout is equal to the reference (or alternatively, preset) flow rate.

The sensor unit 30 may be installed to the process chamber 10 and may detect an environment inside the process chamber 10. In an example embodiment, the sensor unit 30 may include a pressure sensor measuring pressure of the process chamber 10 and a temperature sensor measuring temperature inside the process chamber 10. The sensor unit 30 may transmit a signal S2 corresponding to measured environment information inside the process chamber 10 to the monitoring apparatus 50 in real-time.

The exhaust unit 40 may exhaust a gas inside the process chamber 10 through the gas exhaust port 115 of the process chamber 10. The process gas or by-product of a reaction inside the process chamber 10 may be exhausted from the process chamber 10 by the exhaust unit 40. The exhaust unit 40 may adjust pressure of the process chamber 10 by adjusting a flow of an exhaust gas exhausted from the process chamber 10.

The exhaust unit 40 may include a vacuum pump 401 and an exhaust valve 400, and adjust an exhaust speed of the exhaust gas exhausted from the process chamber 10. The exhaust valve 400 may be installed on a gas exhaust line connecting the vacuum pump 401 to the gas exhaust port 115 of the process chamber 10. The exhaust valve 400 may adjust the pressure inside the process chamber 10 by adjusting the exhaust speed. The exhaust valve 400 may transmit a signal S3 corresponding to the exhaust speed to the monitoring apparatus 50 in real-time.

The monitoring apparatus 50 may detect a flow of the process gas supplied to the process chamber 10. In an example embodiment, the monitoring apparatus 50 may use pressure inside the process chamber 10 and an exhaust speed of the exhaust gas exhausted through the exhaust valve 400 to detect a flow of the process gas. The monitoring apparatus 50 may monitor whether the process gas is being supplied to the process chamber 10 at a flow equal to the reference (or alternatively, preset) flow rate.

For example, a flow of the process gas supplied to the process chamber 10 may have a relation shown in Equation (1) below with the pressure of the process chamber 10 and the exhaust speed of the exhaust gas exhausted through the exhaust valve 400.

Q∝a<P·S (1)

where Q is an outflow rate Qout of the process gas flowing from or exiting the mass flow controller 200 and means an actual flow of the process gas supplied to the process chamber 10, P is the pressure inside the process chamber 10 measured by the sensor unit 30, and S is the exhaust speed of the exhaust gas exhausted through the exhaust valve 400.

As illustrated in Equation 1, the actual flow of the process gas supplied to the process chamber 10 may be proportional to the pressure inside the process chamber 10 and the exhaust speed. That is, when the pressure inside the process chamber 10 is constant, the exhaust speed changes depending on the actual flow of the process gas supplied to the process chamber 10. In other words, in the case where the pressure inside the process chamber 10 is constant, when the exhaust speed is raised, the actual flow of the process gas supplied to the process chamber 10 increases. On the contrary, when the exhaust speed is reduced, the actual flow of the process gas supplied to the process chamber 10 is reduced.

Also, as illustrated in Equation 1, in the case where the exhaust speed is constant, when the pressure inside the process chamber 10 increases, the actual flow of the process gas supplied to the process chamber 10 increases. On the contrary, when the pressure inside the process chamber 10 is reduced, the actual flow of the process gas supplied to the process chamber 10 is reduced.

Therefore, a change of the actual flow of the process gas supplied to the process chamber 10 may be known by monitoring the pressure inside the process chamber 10 and the exhaust speed of the exhaust gas exhausted through the exhaust valve 400.

Furthermore, the monitoring apparatus 50 may detect whether the mass flow controller 200 is abnormal. The monitoring apparatus 50 may determine whether a defect occurs in the mass flow controller 200 by analyzing the correction signal S1, the signal S2 corresponding to environment information inside the process chamber 10 measured by the sensor unit 30, and the signal S3 corresponding to the exhaust speed of the exhaust gas exhausted through the exhaust valve 400.

For example, even though a change of a flow of the process gas supplied to the process chamber 10 is determined through monitoring of the environment information inside the process chamber 10 and the exhaust speed of the exhaust gas exhausted through the exhaust valve 400, if an actual flow of the process gas supplied to the process chamber 10 is not controlled by the mass flow controller 200 such that the actual flow of the process gas is equal to a reference (or alternatively, preset) flow rate, it may be determined that a defect has occurred in the mass flow controller 200.

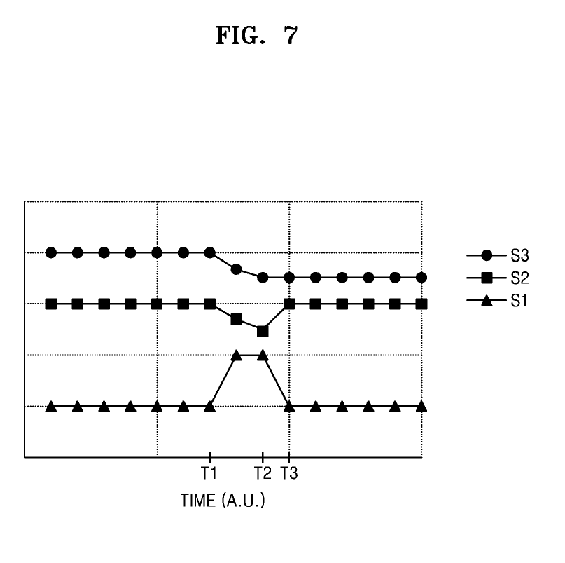

Furthermore, when a defect has occurred in the mass flow controller 200, the monitoring apparatus 50 may detect a cause of the defect having occurred in the mass flow controller 200, that is, a defective portion of the mass flow controller 200, and detect a time at which the defect has occurred in the mass flow controller 200 by analyzing the correction signal S1, the signal S2 corresponding to environment information inside the process chamber 10 measured by the sensor unit 30, and the signal S3 corresponding to the exhaust speed of the exhaust gas exhausted through the exhaust valve 400. A method of detecting a cause of the defect having occurred in the mass flow controller 200 is described in more detail with reference to FIGS. 7 to 9.

In an example embodiment, the monitoring apparatus 50 may include a receiver 510 and a determining unit 520.

The receiver 510 may include a first receiver 511 receiving the correction signal S1 transmitted from the mass flow controller 200, a second receiver 513 receiving the signal S2 corresponding to environment information inside the process chamber 10 transmitted from the sensor unit 30, and a third receiver 515 receiving a signal S3 corresponding to the exhaust speed of the exhaust gas exhausted through the exhaust valve 400. Though not shown in the drawings, the monitoring apparatus 50 may have a database for storing signals received in the receiver 510.

The determining unit 520 may include an algorithm for processing signals received in the receiver 510, and determine whether the mass flow controller 200 is abnormal based on the signals received in the receiver 510. Also, in the case where a defect of the mass flow controller 200 is detected, the determining unit 520 may detect a cause of the defect of the mass flow controller 200. For example, the determining unit 520 may be configured to detect at least one of a defect of the flow sensor 210 or a defect of the valve unit 220.

In an example embodiment, the monitoring apparatus 50 may include a general personal computer (PC), a workstation, and a supercomputer. An analysis program for analyzing the signals may be installed in the monitoring apparatus 50.

In order to detect whether a flow of the process gas supplied to the process chamber 10 is abnormal, a flow of the process gas supplied to the process chamber 10 may be monitored by using a signal obtained from the mass flow controller 200. For example, a flow of the process gas supplied to the process chamber 10 is monitored by using the correction signal S1 for correcting a difference between a flow of the process gas measured by the flow sensor 210 of the mass flow controller 200, and a reference (or alternatively, preset) flow rate. However, in the case where a defect occurs in the mass flow controller 200, a problem that a flow of the process gas different from the reference (or alternatively, preset) flow rate is supplied to the process chamber 10 may not be detected by monitoring only the correction signal S1. For example, even when an actual flow of the process gas supplied to the process chamber 10 is different from the reference (or alternatively, preset) flow rate, in the case where a defect occurs in the flow sensor 210, an erroneous correction signal S1 representing a flow of the process gas equal to the reference (or alternatively, preset) flow rate being supplied to the process chamber 10 may be generated. Also, in the case where a defect occurs in the valve unit 220, even when a correction signal S1 suitable for correcting a flow of the process gas with the reference (or alternatively, preset) flow rate occurs, a flow of the process gas different from the reference (or alternatively, preset) flow rate may flow from the mass flow controller 200 due to a malfunction of the valve unit 220. In this case, because a flow of the process gas different from the reference (or alternatively, preset) flow rate is supplied to the process chamber 10, yield and quality of semiconductor products may be reduced.

The apparatus 1 for manufacturing a semiconductor device may be implement as a virtual metrology (VM) monitoring system which is configured to detect whether the mass flow controller 200 is abnormal by using the correction signal S1, the environment information inside the process chamber 10 measured by the sensor unit 30, and the exhaust speed of the exhaust gas exhausted through the exhaust valve 400 as parameters. The apparatus 1 for manufacturing a semiconductor device may detect a defect of the mass flow controller 200 by analyzing the environment information inside the process chamber 10 and the exhaust speed of the exhaust gas exhausted through the exhaust valve 400 together with the correction signal S1 for adjusting a flow of the mass flow controller 200. Also, according to the inventive concepts, because whether the mass flow controller 200 is abnormal may be monitored in real-time, a defect of the mass flow controller 200 may be detected at an early stage.

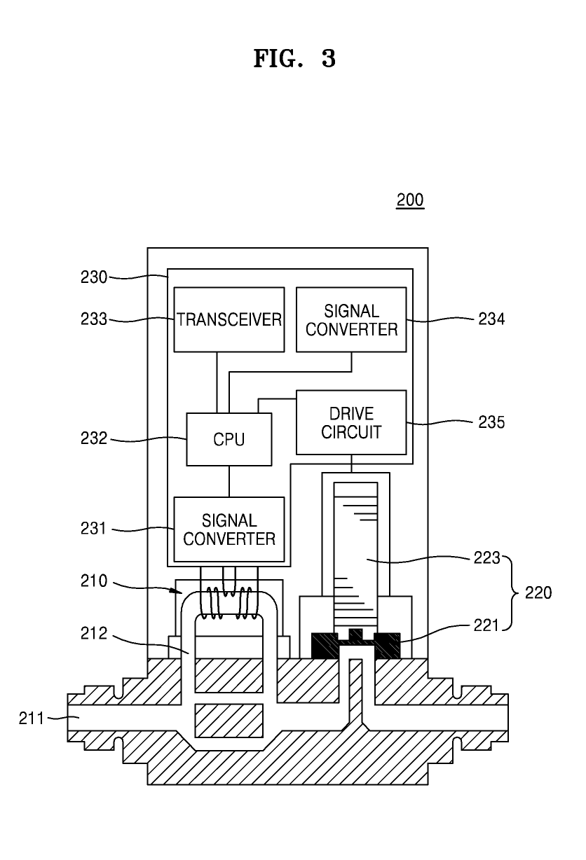

FIG. 3 is a detailed configuration view of the mass flow controller 200 illustrated in FIG. 2.

Referring to FIG. 3, the mass flow controller 200 provides a path through which the process gas flows and may include a main path 211 and a bypass path 212. For example, some of the process gas introduced to a gas inlet of the mass flow controller 200 may flow through the bypass path 212 which branches off from the main path 211, and join the main path 211 before reaching the valve unit 220. The flow sensor 210 may be provided on the bypass path 212 and configured to detect a flow of the process gas flowing through the bypass path 212.

In an example embodiment, the controller 230 may include a first signal converter 231, a processor 232, a transceiver 233, a second signal converter 234, and a driving circuit 235.

The first signal converter 231 may convert an analog signal corresponding to a flow of the process gas detected from the flow sensor 210 to a digital signal and output the same to the processor 232, and the transceiver 233 may receive a reference (or alternatively, preset) signal Sset (see FIG. 2) corresponding to the reference (or alternatively, preset) flow rate and transmit the reference (or alternatively, preset) signal to the processor 232. The processor 232 may generate the correction signal S1 (see FIG. 2) based on the reference (or alternatively, preset) signal and the signal corresponding to the flow of the process gas detected by the flow sensor 210. The correction signal S1 generated by the processor 232 may be converted to a signal suitable for driving the valve unit 220, for example, an analog signal by the second signal converter 234. The driving circuit 235 may drive the valve unit 220 by using the correction signal S1 transmitted from the controller 230.

The valve unit 220 may adjust an outflow rate Qout (see FIG. 2) of the process gas flowing from the mass flow controller 200 by adjusting an opening degree of the channel prepared in the mass flow controller 200 based on the correction signal S1 applied from the controller 230. In an example embodiment, the valve unit 220 may include a diaphragm 221 which may open/close the channel and an actuator 223 operating in response to the correction signal S1 and connected to the diaphragm 221.

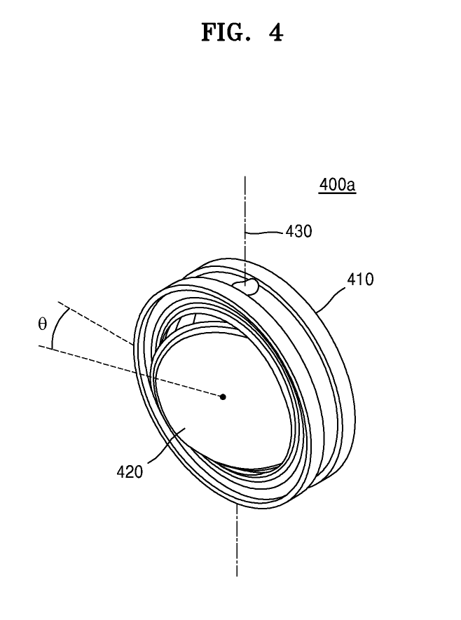

FIG. 4 is a perspective view of an exhaust valve 400a according to an example embodiment.

Referring to FIG. 4, the exhaust valve 400a may include a butterfly valve configured to control an exhaust speed of an exhaust gas exhausted through the exhaust valve 400a depending on an open angle θ.

In an example embodiment, the exhaust valve 400a may include a flange 410 providing a channel through which an exhaust gas may flow, and a rotation body 420 may be rotatably installed on the flange 410. The rotation body 420 may be configured to rotate around a rotational axis 430. The exhaust speed may be adjusted depending on the open angle θ by which the rotation body 420 rotates around the rotational axis 430 from a state in which the rotation body 420 closes the channel provided by the flange 410.

The exhaust valve 400a may transmit the open angle θ to the monitoring apparatus 50 (See FIG. 1) in real-time, and the monitoring apparatus 50 may detect the exhaust speed of the exhaust gas exhausted through the exhaust valve 400a by analyzing the open angle θ.

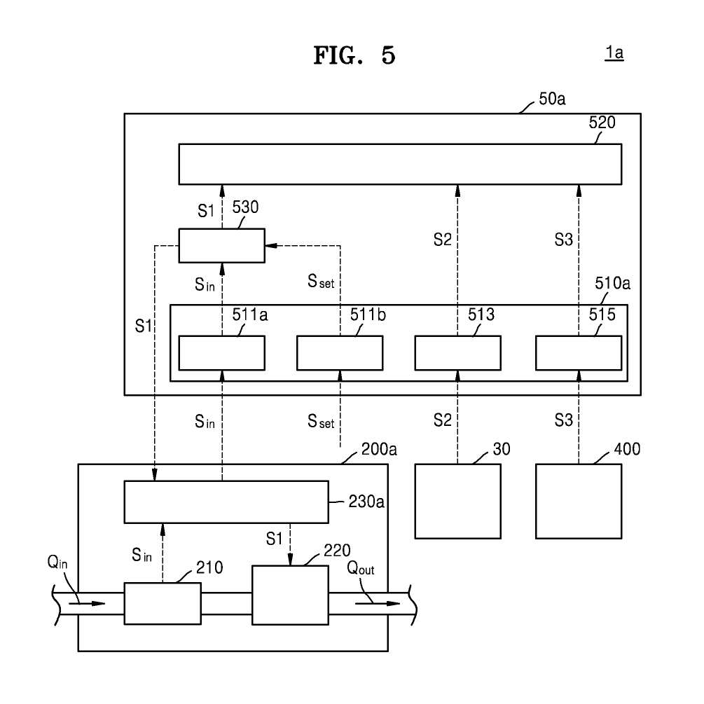

FIG. 5 is a block diagram of an apparatus 1a for manufacturing a semiconductor device according to an example embodiment. The apparatus 1a for manufacturing a semiconductor device illustrated in FIG. 5 is the same as or substantially similar to the apparatus 1 for manufacturing a semiconductor device described with reference to FIGS. 1 and 2 except that the correction signal S1 is generated by the apparatus 1a for manufacturing a semiconductor device and transmitted to a mass flow controller 200a. In FIG. 5, descriptions which are same as those made with reference to FIGS. 1 and 2 are omitted or briefly made.

Referring to FIG. 5, a monitoring apparatus 50a may receive a signal Sin corresponding to an inflow rate Qin introduced to the mass flow controller 200a and a reference (or alternatively, preset) signal Sset corresponding to a reference (or alternatively, preset) flow rate, and generate the correction signal S1 based on the signal Sin corresponding to the inflow rate Qin and the reference (or alternatively, preset) signal Sset.

For example, the monitoring apparatus 50a may include a receiver 510a, a determining unit 520, and a correction signal generator 530.

The receiver 510a may include a first sub-receiver 511a receiving the signal Sin corresponding to the inflow rate Qin transmitted from the controller 230a of the mass flow controller 200a, and a second sub-receiver 511b receiving the reference (or alternatively, preset) signal Sset transmitted from outside. The signal Sin corresponding to the inflow rate Qin and the reference (or alternatively, preset) signal Sset received in the first sub-receiver 511a and the second sub-receiver 511b, respectively, are transmitted to the correction signal generator 530, and the correction signal generator 530 may generate the correction signal S1 based on the signal Sin corresponding to the inflow rate Qin and the reference (or alternatively, preset) signal Sset.

The correction signal generator 530 may transmit the generated correction signal S1 to the determining unit 520 and the mass flow controller 200a. The mass flow controller 200a may adjust driving of the valve unit 220 such that the outflow rate Qout flowing from the mass flow controller 200a is equal to the reference (or alternatively, preset) flow rate based on the correction signal S1 transmitted from the monitoring apparatus 50a.

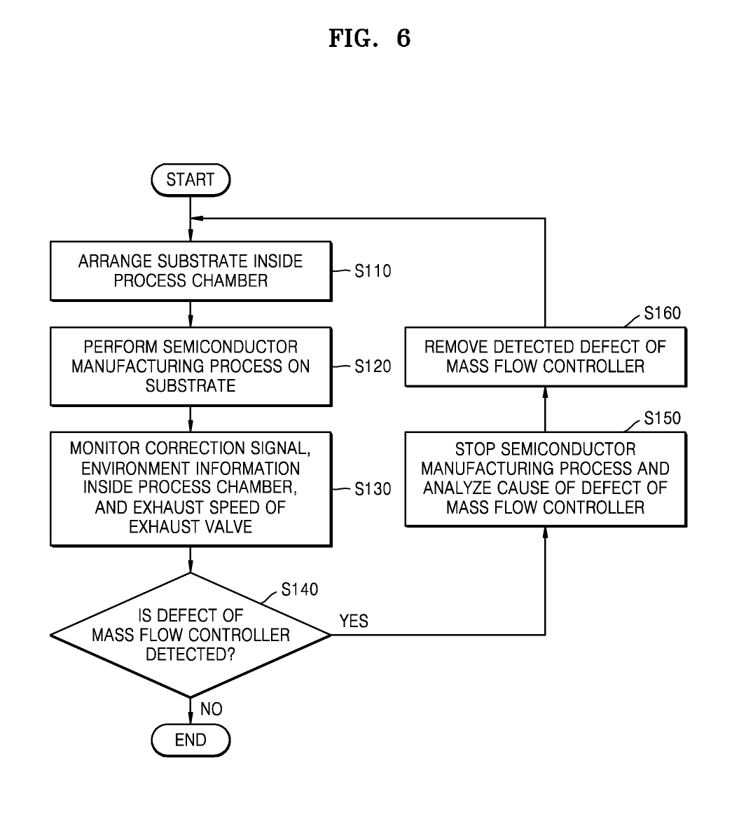

FIG. 6 is a flowchart of a method of manufacturing a semiconductor device by using a method of monitoring the mass flow controller 200 according to an example embodiment. For convenience of description, description is made with reference to FIGS. 1 and 2 together.

Referring to FIG. 6, the substrate W is arranged on the substrate supporter 111 inside the process chamber 10 (S110).

After the substrate W is arranged inside the process chamber 10, a semiconductor process, for example, a deposition process, an etching process, a diffusion process, a dry process, and a washing process may be performed on the substrate W (S120). To perform a semiconductor manufacturing process on the substrate W, a flow of the process gas supplied to the process chamber 10 may be controlled by using the mass flow controller 200. The mass flow controller 200 may supply a reference (or alternatively, preset) flow rate of the process gas to the process chamber 10 according to a process recipe.

While the semiconductor manufacturing process is performed, the correction signal S1, the environment information inside the process chamber 10, and the exhaust speed of the exhaust gas exhausted through the exhaust valve 400 are monitored (S130). The correction signal S1 is a signal corresponding to a difference between an inflow rate Qin of the process gas introduced to the mass flow controller 200 and a reference (or alternatively, preset) flow rate. The correction signal S1 may be generated by the mass flow controller 200 and transmitted to the monitoring apparatus 50. The sensor unit 30 may measure the environment information inside the process chamber 10, for example, temperature and/or pressure of the process chamber 10, and transmit a signal corresponding to the measured value to the monitoring apparatus 50 in real-time. Also, the exhaust valve 400 may transmit information which may represent an exhaust speed, for example, information regarding an open angle 9 (see FIG. 4) of a butterfly valve to the monitoring apparatus 50.

Whether the mass flow controller 200 is abnormal is determined based on the correction signal S1, the environment information of the process chamber 10, and the exhaust speed of the exhaust gas exhausted through the exhaust valve 400 (S140). Whether the mass flow controller 200 is abnormal may be determined by the monitoring apparatus 50, and detected in real-time while the semiconductor manufacturing process is performed.

In the case where a defect of the mass flow controller 200 is not detected (NO in S140), monitoring for detecting a defect of the mass flow controller 200 is ended, and the semiconductor manufacturing process for the substrate W is completed.

Meanwhile, in the case where a defect of the mass flow controller 200 is detected (YES in S140), the semiconductor manufacturing process for the substrate W is stopped, and a cause of the defect of the mass flow controller 200 is analyzed (S150). In an example embodiment, the monitoring apparatus 50 may detect a defect of the flow sensor 210 of the mass flow controller 200 and/or a defect of the valve unit 220 of the mass flow controller 200 by monitoring the correction signal S1, the pressure inside the process chamber 10, and a change in the exhaust speed of the exhaust gas exhausted through the exhaust valve 400 over time. The method of detecting a cause of a defect of the mass flow controller 200 is described in more detail with reference to FIGS. 7 to 9.

After a cause of the defect of the mass flow controller 200 is detected, the detected defect of the mass flow controller 200 may be removed (S160). For example, maintenance may be performed on the mass flow controller 200, the mass flow controller 200 may be replaced, or an appropriate feedback operation may be performed such that a flow of the process gas supplied to the process chamber 10 is calibrated to be equal to a reference (or alternatively, preset) flow rate. When a defect of the mass flow controller 200 is removed, the semiconductor manufacturing process for the substrate W may be performed and monitoring of the mass flow controller 200 may be performed.

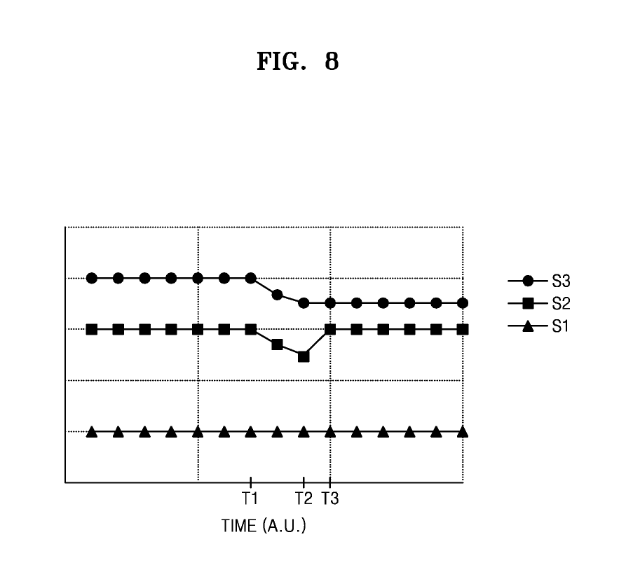

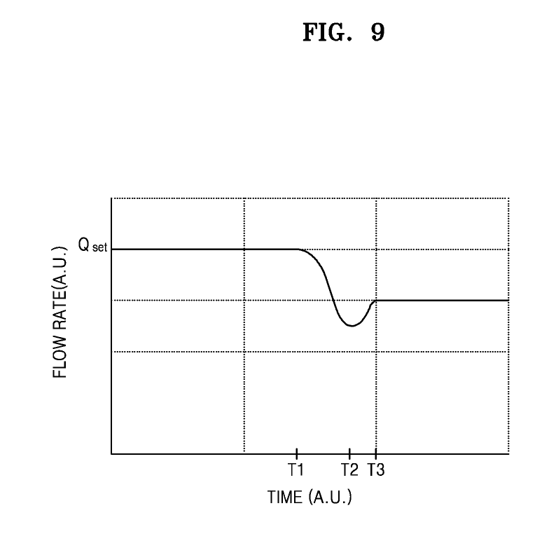

FIGS. 7 to 9 are views for explaining a method of determining a cause of a defect of the mass flow controller 200. FIGS. 7 and 8 are graphs illustrating correction signals S1, signals S2 corresponding to pressure inside the process chamber 10, and signals S3 corresponding to an exhaust speed of the exhaust gas exhausted through the exhaust valve 400. FIG. 9 is a graph illustrating a flow of the process gas supplied to the process chamber 10 corresponding to the graphs of FIGS. 7 and 8. For convenience of description, description is made with reference to FIGS. 1 and 2 together.

Referring to FIG. 7, to detect a cause of a defect of the mass flow controller 200, the correction signal S1, the signal S2 corresponding to pressure inside the process chamber 10, and the signal S3 corresponding to the exhaust speed of the exhaust gas exhausted through the exhaust valve 400 may be synchronized on a same time axis. In the graph illustrated in FIG. 7, it is shown that the pressure inside the process chamber 10 gradually decreases from a reference (or alternatively, preset) pressure between a first time point T1 and a second time point T2, increases between the second time point T2 and a third time point T3 as the exhaust speed of the exhaust gas exhausted through the exhaust valve 400 is reduced, and maintains the reference (or alternatively, preset) pressure after the third time point T3.

As described above, because a flow of the process gas supplied to the process chamber 10 is proportional to the pressure inside the process chamber 10 and the exhaust speed of the exhaust gas exhausted through the exhaust valve 400, the flow of the process gas supplied to the process chamber 10 becomes less than a reference (or alternatively, preset) flow rate Qset after the first time point T1 as illustrated in FIG. 9. If there is a defect of the mass flow controller 200, a flow of the process gas different from the reference (or alternatively, preset) flow Qset may be supplied to the process chamber 10 after the first time point T1.

As illustrated in FIG. 7, the correction signal S1 changes at the first time point T1 from which a flow of the process gas supplied to the process chamber 10 starts to decrease. Because the flow of the process gas supplied to the process chamber 10 is being decreased in proportion to decrease in at least one of (or both) the pressure inside the process chamber 10 or the exhaust speed of the exhaust gas exhausted through the exhaust valve 400, the correction signal S1 is erroneously generated. Due to such an erroneous correction signal S1, a problem may occur in the flow of the process gas supplied to the process chamber 10. For example, when there is a defect of the flow sensor 210, an erroneous inflow rate Qin is measured. The erroneous inflow rate Qin, may generate a correction signal S1, which is erroneous. Then, the valve unit 220 may operate in response to the correction signal S1 such that a flow of the process gas less than the present flow Qset flows from the mass flow controller 200. Therefore, as illustrated in FIG. 7, when the correction signal S1 changes and at least one (or both) of the pressure inside the process chamber 10 or the exhaust speed of the exhaust gas exhausted through the exhaust valve 400 changes simultaneously with the correction signal S1, it may be determined that a defect has occurred in the flow sensor 210.

Also, in the graph illustrated in FIG. 8, it is shown that the pressure inside the process chamber 10 and the exhaust speed of the exhaust gas exhausted through the exhaust valve 400 change in a same manner as that of FIG. 7. That is, as illustrated in FIG. 9, it is shown that a flow of the process gas supplied to the process chamber 10 after the first time point T1 becomes less than the reference (or alternatively, preset) flow rate Qset.

As illustrated in FIG. 8, it is shown that even when the correction signal S1 does not change, a flow of the process gas supplied to the process chamber 10 may be reduced after the first time point T1. That is, although an inflow rate Qin equal to the reference (or alternatively, preset) flow rate Qset is detected by the flow sensor 210 and so the correction signal S1 representing that correction of a flow of the process gas is not generated, a flow of the process gas supplied to the process chamber 10 after the first point T1 may become less than the reference (or alternatively, preset) flow rate Qset due to a defect of the valve unit 220. Therefore, as illustrated in FIG. 8, if at least one of the pressure inside the process chamber 10 or the exhaust speed of the exhaust valve 400 changes while the correction signal S1 remains constant, it may be determined that a defect has occurred in the valve unit 220.

Therefore, the apparatus 1 for manufacturing the semiconductor device according to example embodiments may detect a defective element in the mass flow controller 200, and/or accurately detect a time point at which the defect has occurred.

While the inventive concepts have been particularly shown and described with reference to some example embodiments thereof, it will be understood by those of ordinary skill in the art that various changes in form and details may be made therein without departing from the spirit and scope of the inventive concepts as defined by the following claims.

What is claimed is:

1. An apparatus for manufacturing a semiconductor device, the apparatus comprising:
a mass flow controller configured to control a flow of a process gas supplied to a process chamber, the mass flow controller configured to adjust an outflow rate of the process gas exiting the mass flow controller in response to a correction signal, the correction signal generated based on a difference between an inflow rate of the process gas flowing into the mass flow controller and a reference flow rate;
a sensor configured to measure a chamber pressure inside the process chamber;
an exhaust valve configured to adjust an exhaust speed of an exhaust gas exhausted from the process chamber; and
a monitoring apparatus configured to detect a defect of the mass flow controller based on the correction signal, the chamber pressure, and the exhaust speed of the exhaust valve.

2. The apparatus of claim 1, wherein the mass flow controller comprises:
a flow sensor configured to measure the inflow rate and generate a signal corresponding to the inflow rate;
a controller configured to generate the correction signal based on the signal corresponding to the inflow rate and a signal corresponding to the reference flow rate, and transmit the correction signal to the monitoring apparatus; and
a valve configured to adjust the outflow rate in response to the correction signal from the controller.

3. The apparatus of claim 2, wherein the monitoring apparatus is configured to detect at least one of a defect of the flow sensor or a defect of the valve.

4. The apparatus of claim 3, wherein, when the correction signal changes, in a case where at least one of the chamber pressure or the exhaust speed changes, the monitoring apparatus determines that a defect has occurred in the flow sensor.

5. The apparatus of claim 3, wherein the monitoring apparatus is configured to determine that a defect has occurred in the valve if at least one of the chamber pressure or the exhaust speed changes while the correction signal remains constant.

6. The apparatus of claim 2, wherein the monitoring apparatus is configured to detect a time point at which the defect has occurred in the mass flow controller.

7. The apparatus of claim 2, wherein the controller comprises:
a processor configured to generate the correction signal having a voltage value or a current value corresponding to a difference between the signal corresponding to the reference flow rate and the signal corresponding to the inflow rate; and
a driving circuit configured to control driving of the valve in response to the correction signal from the processor.

8. The apparatus of claim 1, wherein the exhaust valve comprises a butterfly valve, which is configured to adjust the exhaust speed by adjusting an open angle thereof, and the exhaust valve is configured to transmit information regarding the adjusted open angle to the monitoring apparatus.

9. The apparatus of claim 1, wherein
the mass flow controller comprises,
a flow sensor configured to measure the inflow rate, and
a valve configured to adjust the outflow rate in response to the correction signal, and
the monitoring apparatus configured to,
generate the correction signal based on a signal corresponding to the inflow rate and a signal corresponding to the reference flow rate, and
transmit the correction signal to the mass flow controller.

10. The apparatus of claim 1, wherein the exhaust valve configured to adjust the exhaust speed such that the chamber pressure is adjusted to a reference pressure.

11. An apparatus for manufacturing a semiconductor device, the apparatus comprising:
a process chamber providing a process space for processing a substrate;
a mass flow controller configured to control a flow rate of a process gas supplied to the process chamber;
a sensor configured to measure a chamber pressure of the process chamber;
an exhaust valve configured to adjust an exhaust speed of an exhaust gas exhausted from the process chamber; and
a monitoring apparatus configured to detect the flow rate of the process gas supplied to the process chamber based on the chamber pressure and the exhaust speed of the exhaust gas.

12. The apparatus of claim 11, wherein the mass flow controller is configured to generate a correction signal based on a difference between an inflow rate of the process gas flowing into the mass flow controller and a reference flow rate.

13. The apparatus of claim 12, wherein the mass flow controller comprises:
a flow sensor configured to measure the inflow rate; and
a valve configured to receive the correction signal and adjust the flow rate of the process gas supplied to the process chamber in response to the correction signal.

14. The apparatus of claim 13, wherein if the flow rate of the process gas supplied to the process chamber is different from the reference flow rate, the monitoring apparatus is configured to determine that a defect has occurred in the mass flow controller.

15. The apparatus of claim 13, wherein the monitoring apparatus is configured to determine,
that a defect has occurred in the flow sensor if the correction signal and at least one of the pressure of the process chamber or the exhaust speed changes, and
that a defect has occurred in the valve if at least one of the chamber pressure or the exhaust speed changes while the correction signal remains constant.

16. A monitoring apparatus for detecting a defect of a mass flow controller controlling a flow of a process gas supplied to a process chamber, the monitoring apparatus is configured to,
generate a correction signal based on a difference between an inflow rate of the process gas flowing to the mass flow controller and a reference flow rate; and
detect a defect of the mass flow controller based on the correction signal, environment information inside the process chamber, and an exhaust speed of an exhaust gas exhausted from the process chamber.

17. The monitoring apparatus of claim 16, wherein the monitoring apparatus is further configured to,
receive the correction signal, the environment information inside the process chamber, and the exhaust speed, and
determine whether the mass flow controller is abnormal by monitoring the correction signal, the environment information inside the process chamber, and the exhaust speed over time.

18. The monitoring apparatus of claim 16, wherein the monitoring apparatus is configured to detect at least one of a defect of a flow sensor or a defect of a valve, the flow sensor provided to the mass flow controller to measure the inflow rate, and the valve provided to the mass flow controller to adjust an outflow rate of the process gas exiting the mass flow controller.

19. The monitoring apparatus of claim 16, wherein the monitoring apparatus is configured to,
generate the correction signal based on a signal corresponding to the inflow rate and a signal corresponding to the reference flow rate, and
transmit the correction signal to the mass flow controller.

20. The monitoring apparatus of claim 16, wherein the monitoring apparatus is configured to detect a defect of the mass flow controller in real-time while a substrate is being processed in the process chamber.
